(19) United States
(12) Patent Application Publication
(10) Pub. No.: US 2023/0163221 A1
(43) Pub. Date: May 25, 2023

(54) SCHOTTKY BARRIER DIODE AND METHOD FOR MANUFACTURING SAME

(71) Applicant: ENKRIS SEMICONDUCTOR, INC., Suzhou (CN)

(72) Inventor: Kai Cheng, Suzhou (CN)

(73) Assignee: ENKRIS SEMICONDUCTOR, INC., Suzhou (CN)

(21) Appl. No.: 17/987,564

(22) Filed: Nov. 15, 2022

(30) Foreign Application Priority Data
Nov. 19, 2021 (CN) 202111400632.3

(51) Int. Cl. H01L 29/872; H01L 29/06; H01L 29/20; H01L 29/205; H01L 29/66; H01L 29/778

(52) U.S. Cl. CPC H01L 29/872; H01L 29/0619; H01L 29/2003; H01L 29/205; H01L 29/66143; H01L 29/7787

(57) ABSTRACT

The present disclosure provides a Schottky barrier diode and a method for manufacturing same. The Schottky barrier diode includes a substrate, a heterojunction structure, a P-type semiconductor layer, an anode and a cathode. The P-type semiconductor layer includes a plurality of P-type semiconductor sub-blocks, and the plurality of P-type semiconductor sub-blocks between the anode and the cathode are spaced apart.

### CROSS REFERENCE TO RELATED APPLICATIONS

This application claims priority to Chinese Patent Application No. 202111400632.3 filed on Nov. 19, 2021, the entire content of which is incorporated herein by reference.

### TECHNICAL FIELD

The present disclosure relates to the field of semiconductor technologies, and in particular to a Schottky barrier diode and a method for manufacturing same.

### BACKGROUND

With the development of microelectronics technology, the performance of traditional first-generation Si semiconductor and second-generation gallium arsenide (GaAs) semiconductor power devices has approached the theoretical limit determined by their materials themselves. In order to further reduce the chip area, increase the operating frequency, increase the operating temperature, reduce the on-resistance, increase the breakdown voltage, reduce the overall volume, and improve the overall efficiency, the wide band semiconductor materials represented by gallium nitride (GaN), with its larger forbidden band width, higher critical breakdown electric field and higher electron saturation drift rate, as well as chemical stability, high temperature resistance, radiation resistance and other excellent physical and chemical properties, in the manufacture of high-performance power devices stand out, the application potential is huge. A Schottky barrier diode is an important GaN-based device, which is a majority carrier semiconductor device with weak minority carrier charge storage effect. Not only GaN semiconductor materials can be used to manufacture GaN Schottky barrier diodes, but also the heterogeneous structure of GaN Schottky barrier diodes can be used to manufacture high-performance devices, such as heterojunction gallium aluminum nitride (AlGaN)/GaN Schottky barrier diodes. The AlGaN/GaN transverse heterojunction Schottky barrier diode has excellent characteristics such as high breakdown voltage, low turn-on resistance and short reverse recovery time, which can easily achieve high current density and power density, and its application in power conversion can greatly improve the system power conversion efficiency and reduce the preparation cost.

However, Schottky barrier diodes also have the problem of high reverse leakage current and poor anti-surge performance.

### SUMMARY

The present disclosure aims to provide a Schottky barrier diode and a method for manufacturing same, to reduce reverse leakage current and improve anti-surge performance.

To this end, a first aspect of the present disclosure provides a Schottky barrier diode, including: a substrate; a heterojunction structure disposed on the substrate; and a P-type semiconductor layer, an anode and a cathode disposed on the heterojunction structure, where the P-type semiconductor layer includes a plurality of P-type semiconductor sub-blocks, the anode and the cathode are disposed at two ends in an extending direction of the plurality of P-type semiconductor sub-blocks, respectively, and the plurality of P-type semiconductor sub-blocks between the anode and the cathode are spaced apart.

Optionally, the plurality of P-type semiconductor sub-blocks are distributed in parallel with each other between the anode and the cathode.

Optionally, at least two of the plurality of P-type semiconductor sub-blocks extend between the anode and the cathode for unequal lengths.

Optionally, for each of the plurality of P-type semiconductor sub-blocks, the P-type semiconductor sub-block includes a first end close to the anode and a second end close to the cathode; and at least one of: the first end of at least one of the plurality of P-type semiconductor sub-blocks has a tip, and/or the second end of at least one of the plurality of P-type semiconductor sub-blocks has a tip.

Optionally, the Schottky barrier diode further includes a passivation layer and a first ion-doped layer, where the first ion-doped layer is disposed between the plurality of P-type semiconductor sub-blocks, the plurality of P-type semiconductor sub-blocks are connected to the first ion-doped layer, the passivation layer is disposed on the first ion-doped layer and exposes the plurality of P-type semiconductor sub-blocks; the anode and the cathode both pass through the passivation layer and the first ion-doped layer to contact the heterojunction structure.

Optionally, the Schottky barrier diode further includes a passivation layer, where the passivation layer integrally covers on the plurality of P-type semiconductor sub-blocks and between the plurality of P-type semiconductor sub-blocks; the anode and the cathode pass through the passivation layer to contact the heterojunction structure.

Optionally, a side surface of at least one of the plurality of P-type semiconductor sub-blocks contacts the anode and does not contact the cathode; or a side surface of at least one of the plurality of P-type semiconductor sub-blocks contacts the cathode and does not contact the anode; or at least one of the plurality of P-type semiconductor sub-blocks is separated into a first section and a second section insulated from each other, where a side surface of the first section contacts the cathode and does not contact the anode, and a side surface of the second section contacts the anode and does not contact the cathode.

Optionally, the anode contacts side surfaces of the plurality of P-type semiconductor sub-blocks and an upper surface of at least one of the plurality of P-type semiconductor sub-blocks; or the cathode contacts side surfaces of the plurality of P-type semiconductor sub-block and an upper surface of at least one of the plurality of P-type semiconductor sub-blocks.

Optionally, the heterojunction structure includes a channel layer close to the substrate and a barrier layer away from the substrate; the anode contacts the barrier layer, or contacts the channel layer, or contacts both the channel layer and the barrier layer; the cathode contacts the barrier layer, or contacts the channel layer, or contacts both the channel layer and the barrier layer.

Optionally, the Schottky barrier diode further includes an N-type semiconductor layer and a first ion-doped layer, the first ion-doped layer is disposed between the plurality of P-type semiconductor sub-blocks, the plurality of P-type semiconductor sub-blocks are connected to the first ion-doped layer, the N-type semiconductor layer is disposed on the first ion-doped layer and exposes the plurality of P-type semiconductor sub-blocks.

A second aspect of the present disclosure provides a method for manufacturing a Schottky barrier diode, including: epitaxially growing a heterojunction structure and a P-type semiconductor layer in sequence on a substrate, where the P-type semiconductor layer includes a plurality of P-type semiconductor sub-blocks, the plurality of P-type semiconductor sub-blocks are spaced apart in a first direction, an angle is formed between an extending direction of each of the plurality of P-type semiconductor sub-blocks and the first direction, the angle is greater than 0° and less than or equal to 90°; and forming an anode and a cathode on the heterojunction structure, the anode and the cathode are disposed at two ends in the extending direction of the plurality of P-type semiconductor sub-blocks, respectively.

Optionally, epitaxially growing the P-type semiconductor layer includes: epitaxially growing a first ion-doped layer over an entire surface of the heterojunction structure; forming a patterned passivation layer on the first ion-doped layer, where the patterned passivation layer has a plurality of first openings, the plurality of first openings are spaced apart in the first direction, and an angle is formed between an extending direction of each of the plurality of first openings and the first direction, the angle is greater than 0° and less than or equal to 90°; and activating exposed dopant ions in the first ion-doped layer with the patterned passivation layer as a mask to form the plurality of P-type semiconductor sub-blocks.

Optionally, epitaxially growing the P-type semiconductor layer includes: epitaxially growing a first ion-doped layer over an entire surface of the heterojunction structure and activating the first ion-doped layer to form a whole P-type semiconductor layer; and patterning the whole P-type semiconductor layer to form the plurality of P-type semiconductor sub-blocks.

Optionally, between epitaxially growing the P-type semiconductor layer and forming the anode and the cathode, the method further includes: integrally forming a passivation layer on the heterojunction structure exposed between the plurality of P-type semiconductor sub-blocks, where the anode and the cathode pass through the passivation layer to contact the heterojunction structure.

Optionally, forming the anode includes: etching the passivation layer to expose the heterojunction structure and a part of an upper surface of at least one of the plurality of P-type semiconductor sub-blocks, where the anode contacts the exposed part of the upper surface and a side surface of the at least one of the plurality of P-type semiconductor sub-blocks and the heterojunction structure; or forming the cathode includes: etching the passivation layer to expose the heterojunction structure and a part of an upper surface of at least one of the plurality of P-type semiconductor sub-blocks, where the cathode contacts the exposed part of the upper surface and a side surface of the at least one of the plurality of P-type semiconductor sub-blocks and the heterojunction structure.

Optionally, epitaxially growing the P-type semiconductor layer includes: epitaxially growing a first ion-doped layer and an N-type semiconductor layer in sequence over an entire surface of the heterojunction structure; patterning the N-type semiconductor layer, such that the N-type semiconductor layer has a plurality of second openings, where an angle is formed between an extending direction of each of the plurality of second openings and the first direction, the angle is greater than 0° and less than or equal to 90°; and activating exposed dopant ions in the first ion-doped layer with the N-type semiconductor layer as a mask to form the plurality of P-type semiconductor sub-blocks.

Optionally, forming the anode and the cathode includes: forming the anode in contact with a side surface of at least one of the plurality of P-type semiconductor sub-blocks and the cathode not in contact with another side surface of the at least one of the plurality of P-type semiconductor sub-blocks, wherein a normal line of the side surface is parallel to a normal line of the another side surface and is parallel to the plane of the substrate; or forming the cathode in contact with a side surface of at least one of the plurality of P-type semiconductor sub-blocks and the anode not in contact with another side surface of the at least one of the plurality of P-type semiconductor sub-blocks, wherein a normal line of the side surface is parallel to a normal line of the another side surface and is parallel to the plane of the substrate; or separating at least one of the plurality of P-type semiconductor sub-blocks into a first section and a second section insulated from each other, forming the cathode in contact with a side surface of the first section, and forming the anode in contact with a side surface of the second section.

After analysis by the inventors, the electric field below the anode is not uniformly distributed in the horizontal direction when the Schottky barrier diode is reverse offset, but the closer to the edge of the electrode, the more dense the electric field line distribution is. As a result, an extreme value of the electric field is to appear at the lower edge of the anode, resulting in an avalanche breakdown easily occurring here, causing an increase in the actual breakdown voltage and reverse leakage current of the AlGaN/GaN Schottky barrier diode.

Based on the above analysis, the present disclosure provides the plurality of P-type semiconductor sub-blocks on the heterojunction structure, and the plurality of P-type semiconductor sub-blocks between the anode and the cathode are spaced apart.

Compared with the related art, the present disclosure has the following beneficial effect.

The surface electric field of the heterojunction structure between the anode and the cathode is redistributed by the plurality of P-type semiconductor sub-blocks, such that the electric field distribution at the lower edge of the anode is improved, to prevent avalanche breakdown here, and increase the actual breakdown voltage and reduce the reverse leakage current of the Schottky barrier diode. In addition, the plurality of P-type semiconductor sub-blocks provide multiple conduction channels between the anode and cathode to prevent surges.

### BRIEF DESCRIPTION OF DRAWINGS

FIG. 1 is a top view illustrating a Schottky barrier diode according to a first embodiment of the present disclosure.

FIG. 2 is a sectional view along line AA in FIG. 1.

FIG. 3 is a top view without an anode and a cathode on the basis of FIG. 1.

FIG. 4 is a sectional view along line BB in FIG. 3.

FIG. 5 is a flowchart illustrating a method for manufacturing the Schottky barrier diode of FIGS. 1 to 4.

FIGS. 6 to 8 are schematic diagrams illustrating intermediate structures corresponding to the process in FIG. 5.

FIG. 9 is a top view illustrating a Schottky barrier diode according to a second embodiment of the present disclosure.

FIG. 10 is a sectional view along the EE line in FIG. 9.

FIG. 11 is a top view illustrating a Schottky barrier diode according to a third embodiment of the present disclosure.

FIG. 12 is a sectional view along line FF in FIG. 11.

FIG. 13 is a top view illustrating a Schottky barrier diode according to a fourth embodiment of the present disclosure.

FIG. 14 is a sectional view along line GG in FIG. 13.

FIG. 15 is a top view illustrating a Schottky barrier diode according to a fifth embodiment of the present disclosure, wherein an anode and a cathode are removed.

FIG. 16 is a top view illustrating a Schottky barrier diode without an anode and a cathode according to a sixth embodiment of the present disclosure.

FIG. 17 is a top view illustrating a Schottky barrier diode according to a seventh embodiment of the present disclosure.

FIG. 18 is a sectional view along a P-type semiconductor sub-block of the Schottky barrier diode of FIG. 17.

FIG. 19 is a top view illustrating a Schottky barrier diode according to an eighth embodiment of the present disclosure.

FIG. 20 is a sectional view along line HH in FIG. 19.

FIG. 21 is a sectional view along line II in FIG. 19.

FIGS. 22 to 25 are schematic diagrams illustrating intermediate structures corresponding to a method for manufacturing the Schottky barrier diode of FIGS. 19 to 21.

FIG. 26 is a schematic diagram illustrating a cross-sectional structure of a Schottky barrier diode according to a ninth embodiment of the present disclosure.

FIG. 27 is a schematic diagram illustrating a cross-sectional structure of a Schottky barrier diode according to a tenth embodiment of the present disclosure.

FIG. 28 is a schematic diagram illustrating a cross-sectional structure of a Schottky barrier diode according to an eleventh embodiment of the present disclosure.

FIG. 29 is a top view illustrating a Schottky barrier diode according to a twelfth embodiment of the present disclosure.

FIG. 30 is a sectional view along line LL in FIG. 29.

For the convenience of understanding of the present disclosure, all reference numerals appearing in the present disclosure are listed below:

substrate 10; heterojunction structure 11; P-type semiconductor layer 12; P-type semiconductor sub-block 121; first end 121a; second end 121b; anode 13; cathode 14; passivation layer 15; channel layer 111; barrier layer 112; first section 1211; second section 1212; N-type semiconductor layer 16; first ion-doped layer 17; first opening 15a; Schottky barrier diode 1, 2, 3, 4, 5, 6, 7, 8, 9, 20, 21, 22.

### DETAILED DESCRIPTION

In order to make the above purposes, features and advantages of the present disclosure more obvious and understandable, the embodiments of the present disclosure are described in detail below in combination with the accompanying drawings.

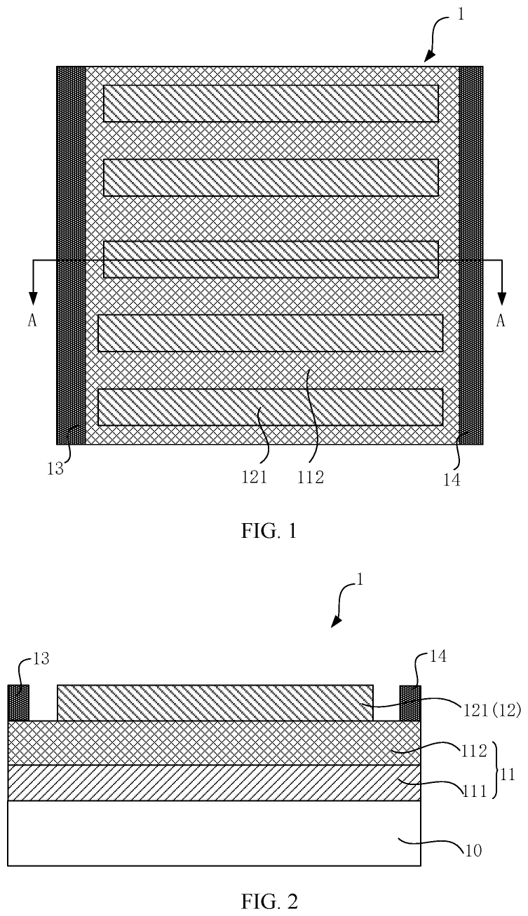

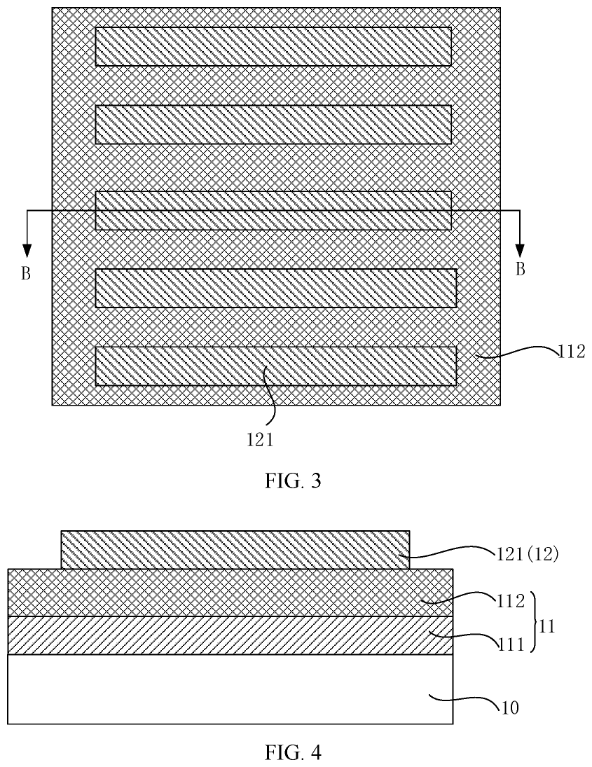

FIG. 1 is a top view illustrating a Schottky barrier diode according to a first embodiment of the present disclosure. FIG. 2 is a sectional view along line AA in FIG. 1. FIG. 3 is a top view without an anode and a cathode on the basis of FIG. 1. FIG. 4 is a sectional view along line BB in FIG. 3.

Referring to FIGS. 1 to 4, the Schottky barrier diode 1 includes a substrate 10, a heterojunction structure 11, a P-type semiconductor layer 12, an anode 13 and a cathode 14; the P-type semiconductor layer 12 includes a plurality of P-type semiconductor sub-blocks 121, the anode 13 and the cathode 14 are disposed at two ends in an extending direction of the plurality of P-type semiconductor sub-blocks 121, respectively, and the plurality of P-type semiconductor sub-blocks 121 between the anode 13 and the cathode 14 are spaced apart.

A material of the substrate 10 may be a material such as sapphire, silicon carbide, silicon, or diamond.

Referring to FIG. 2, the heterojunction structure 11 includes a channel layer 111 close to the substrate 10 and a barrier layer 112 away from the substrate 10. An interface between the channel layer 111 and the barrier layer 112 may form two-dimensional electron gas.

Materials of both the channel layer 111 and the barrier layer 112 may include GaN-based materials, and a forbidden band width of the barrier layer 112 is greater than a forbidden band width of the channel layer 111. The material of the barrier layer 112 may be AlGaN and the material of the channel layer 111 may be GaN.

In this embodiment, the P-type semiconductor layer 12, the anode 13 and the cathode 14 are disposed in the same layer. A material of the P-type semiconductor layer 12 may be a GaN-based material, and the P-type doping element may be at least one of Mg, Zn, Ca, Sr, or Ba. The P-type doping element, when activated, may provide holes that consume the two-dimensional electron gas at the interface of the heterojunction structure 11. A depletion layer confined only within the barrier layer 112 is formed below each P-type semiconductor sub-block 121, and when the Schottky barrier diode 1 is reverse offset, the distribution of the depletion layers spaced apart allows the surface electric field of the heterojunction structure 11 between the anode 13 and the cathode 14 to be redistributed, so as to improve the reverse conduction performance. Thus, the electric field distribution at the lower edge of the anode 13 and the cathode 14 can be improved to prevent avalanche breakdown here, increase the actual breakdown voltage and reduce the reverse leakage current of the Schottky barrier diode 1.

In this embodiment, the distribution of various P-type semiconductor sub-blocks 121 between the anode 13 and the cathode 14 spaced apart means that the anode 13 and the cathode 14 are disposed at two ends in an extending direction of each P-type semiconductor sub-block 121, respectively. Specifically, referring to FIG. 3, the various P-type semiconductor sub-blocks 121 may be distributed in parallel with each other between the anode 13 and the cathode 14, i.e., the various P-type semiconductor sub-blocks 121 are distributed from top to bottom in FIG. 3. In other embodiments, the P-type semiconductor sub-blocks 121 are distributed from top to bottom in FIG. 3 while an angle may be formed between the extending directions of at least two P-type semiconductor sub-blocks 121, where the angle is greater than 0° and less than 90°. The above distribution of the plurality of P-type semiconductor sub-blocks 121 may provide a plurality of conduction channels between the anode 13 and the cathode 14.

In this embodiment, with reference to FIG. 2, Schottky contact is formed between the anode 13 and the barrier layer 112, and ohmic contact is formed between the cathode 14 and the barrier layer 112. A material of the cathode 14 may be a metal, such as Ti/Al/Ni/Au, Ni/Au, Al, Zr, Hf, etc.; and a material of the anode 13 may be a metal, such as Ti/Al/Ni/Au, Ni/Au, etc.

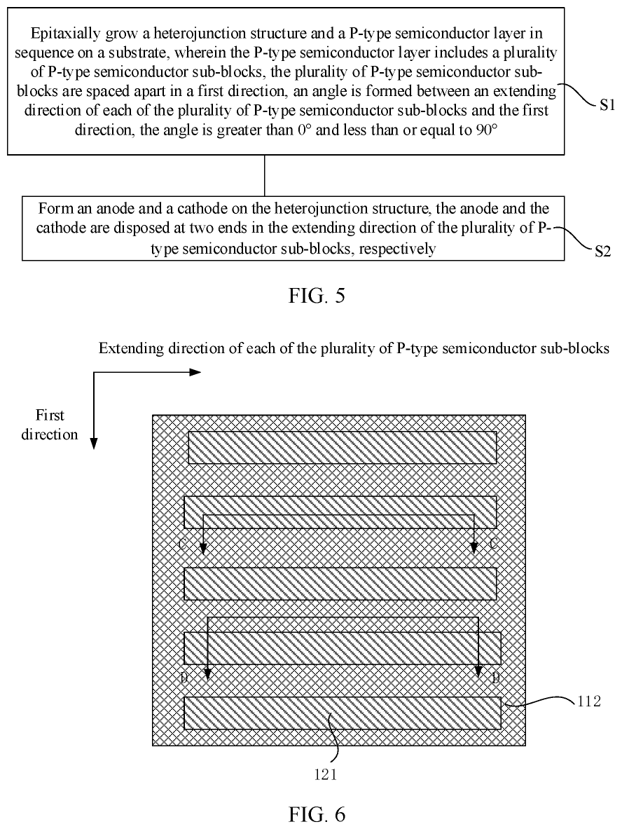

The first embodiment of the present disclosure also provides a method for manufacturing the Schottky barrier diode of FIGS. 1 to 4. FIG. 5 is a flowchart illustrating a method for manufacturing the Schottky barrier diode of FIGS. 1 to 4. FIGS. 6 to 8 are schematic diagrams illustrating intermediate structures corresponding to the process in FIG. 5.

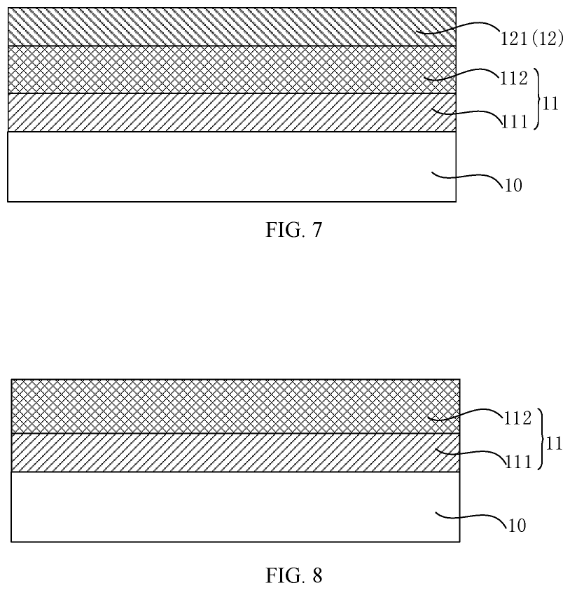

Referring to step S1 in FIG. 5 and FIGS. 6 to 8, the heterojunction structure 11 and the P-type semiconductor layer 12 are epitaxially grown in sequence on the substrate 10, the P-type semiconductor layer 12 includes the plurality of P-type semiconductor sub-blocks 121, the plurality of P-type semiconductor sub-blocks 121 are spaced apart in a first direction, and an angle is formed between the extending direction of each P-type semiconductor sub-block 121 and the first direction, the angle is greater than 0° and less than or equal to 90°. FIG. 6 illustrates the plurality of P-type semiconductor sub-blocks formed by patterning the whole P-type semiconductor layer; FIG. 7 is a sectional view along line CC in FIG. 6; and FIG. 8 is a sectional view along line DD in FIG. 6.

A material of the substrate 10 may be a material such as sapphire, silicon carbide, silicon, or diamond.

In this embodiment, step S1 may include step S11 and step S12.

At step S11, the first ion-doped layer is epitaxially grown over an entire surface of the heterojunction structure 11, and activated to form a whole P-type semiconductor layer.

The primary material of the first ion-doped layer may be a GaN-based material, and the doping element may be at least one of Mg, Zn, Ca, Sr, or Ba. The doping element can be doped in situ during epitaxial growth of the GaN-based material or may be doped by ion injection after epitaxial growth of the GaN-based material.

The epitaxial growth process for GaN-based material may be metal-organic chemical vapor deposition (MOCVD) technique. When growing GaN-based materials by MOCVD technique, a large number of H atoms are present in the MOCVD growth environment, and the host dopant in GaN-based materials, for example the Mg elements, will be passivated by a large number of H atoms without producing holes. In other words, the dopant ions in the first ion-doped layer are not activated, resulting in holes not being generated and not forming the P-type semiconductor layer.

Activation of the dopant ions in the first ion-doped layer can be achieved by an annealing process.

In the annealing process, the entire surface of the first ion-doped layer is exposed, H atoms can escape, the host dopant, such as Mg elements, in the GaN-based material can generate holes and the P-type semiconductor layer is formed.

At step S12, referring to FIGS. 6 to 8, the whole P-type semiconductor layer is patterned to form the plurality of P-type semiconductor sub-blocks 121.

The patterning of the whole P-type semiconductor layer may be achieved by dry etching or wet etching.

In this embodiment, the extending direction of each of the plurality of P-type semiconductor sub-blocks 121 is perpendicular to the first direction, as shown in FIG. 6. In other embodiments, an angle greater than 0° and less than 90° is formed between the extending direction of each of the plurality of P-type semiconductor sub-blocks 121 and the first direction, for example, the plurality of P-type semiconductor sub-blocks 121 have different extending directions.

With reference to step S2 in FIG. 5, FIG. 1 and FIG. 2, the anode 13 and the cathode 14 are formed on the heterojunction structure 11, and the anode 13 and the cathode 14 are disposed at two ends in the extending direction of each P-type semiconductor sub-block 121, respectively.

The material of the cathode 14 may be metal that can form an ohmic contact with the barrier layer 112, for example Ti/Al/Ni/Au, Ni/Au, Al, Zr, Hf, and so on; the material of the anode 13 may be metal that can form a Schottky contact with the barrier layer 112, for example Ti/Al/Ni/Au, Ni/Au, and so on. The cathode 14 and the anode 13 can both be formed by physical vapor deposition or chemical vapor deposition.

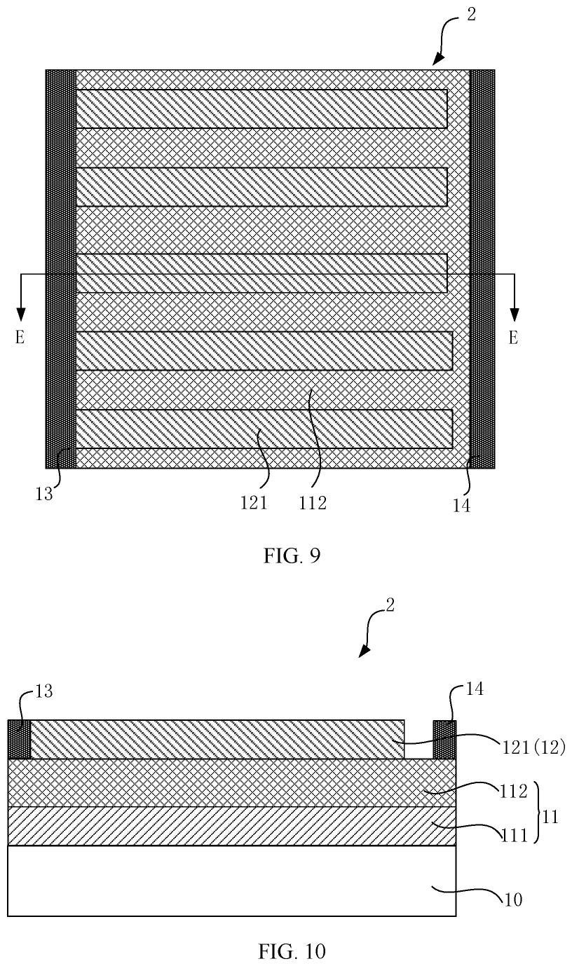

FIG. 9 is a top view illustrating a Schottky barrier diode according to a second embodiment of the present disclosure. FIG. 10 is a sectional view along the EE line in FIG. 9.

Referring to FIG. 9 and FIG. 10, the Schottky barrier diode 2 of this second embodiment is substantially the same as the Schottky barrier diode 1 of the first embodiment, the difference is only that in the second embodiment, the side surfaces of the various P-type semiconductor sub-blocks 121 contact the anode 13 and do not contact the cathode 14.

In the Schottky barrier diode 2, when reverse offset, each P-type semiconductor sub-block 121 and the anode 13 are equipotential, and the depletion layers formed below each P-type semiconductor sub-block 121, although still confined within the barrier layer 112, becomes shallower in depth compared to the depletion layer of the Schottky barrier diode 1 of the first embodiment, and the surface electric field of the heterojunction structure 11 between the anode 13 and the cathode 14 is further redistributed.

In other embodiments, it is also possible that side surfaces of some of the plurality of P-type semiconductor sub-blocks 121 contact the anode 13 and do not contact the cathode 14, and side surfaces of the rest of the plurality of P-type semiconductor sub-blocks 121 neither contact the anode 13 nor the cathode 14.

Accordingly, a method for manufacturing the Schottky barrier diode 2 of this second embodiment differs from the method for manufacturing the Schottky barrier diode 1 of the first embodiment only in that: in step S2, the step of forming the anode 13 and the cathode 14 includes: forming the anode 13 in contact with a side surface of at least one of the plurality of P-type semiconductor sub-blocks 121 and the cathode 14 not in contact with another side surface of the at least one of the plurality of P-type semiconductor sub-blocks 121, where a normal line of the side surface is parallel to a normal line of the another side surface and is parallel to the plane of the substrate.

In this embodiment, after forming the anode 13, a part of the contacted P-type semiconductor sub-block 121 can be removed.

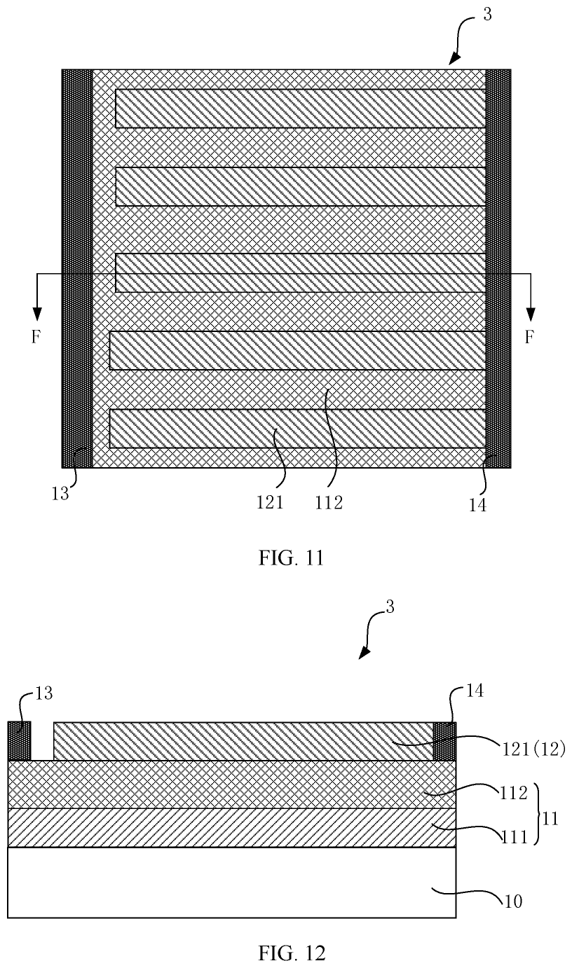

FIG. 11 is a top view illustrating a Schottky barrier diode according to a third embodiment of the present disclosure. FIG. 12 is a sectional view along line FF in FIG. 11.

Referring to FIG. 11 and FIG. 12, the Schottky barrier diode 3 of this third embodiment is substantially the same as the Schottky barrier diodes 1 and 2 of the first and second embodiments, the difference is only that in the third embodiment, the side surfaces of the various P-type semiconductor sub-blocks 121 contact the cathode 14 and do not contact the anode 13.

In the Schottky barrier diode 3, when reverse offset, each P-type semiconductor sub-block 121 and the cathode 14 are equipotential, and the depletion layers formed below each P-type semiconductor sub-block 121, although still confined within the barrier layer 112, becomes deeper in depth compared to the depletion layer of the Schottky barrier diode 1 of the first embodiment, and the surface electric field of the heterojunction structure 11 between the anode 13 and the cathode 14 is further redistributed.

In other embodiments, it is also possible that side surfaces of some of the plurality of P-type semiconductor sub-blocks 121 contact the cathode 14 and do not contact the anode 13, side surfaces of some of the plurality of P-type semiconductor sub-blocks 121 contact the anode 13 and do not contact the cathode 14, and side surfaces of the rest of the plurality of P-type semiconductor sub-blocks 121 neither contact the anode 13 nor the cathode 14.

Accordingly, a method for manufacturing the Schottky barrier diode 3 of this third embodiment differs from the method for manufacturing the Schottky barrier diodes 1 and 2 of the first and second embodiments only in that: in step S2, the step of forming the anode 13 and the cathode 14 includes: forming the cathode 14 in contact with a side surface of at least one of the plurality of P-type semiconductor sub-blocks 121 and the anode 13 not in contact with another side surface of the at least one of the plurality of P-type semiconductor sub-blocks 121, wherein a normal line of the side surface is parallel to a normal line of the another side surface and is parallel to the plane of the substrate.

In this embodiment, after forming the cathode 14, a part of the contacted P-type semiconductor sub-block 121 can be removed.

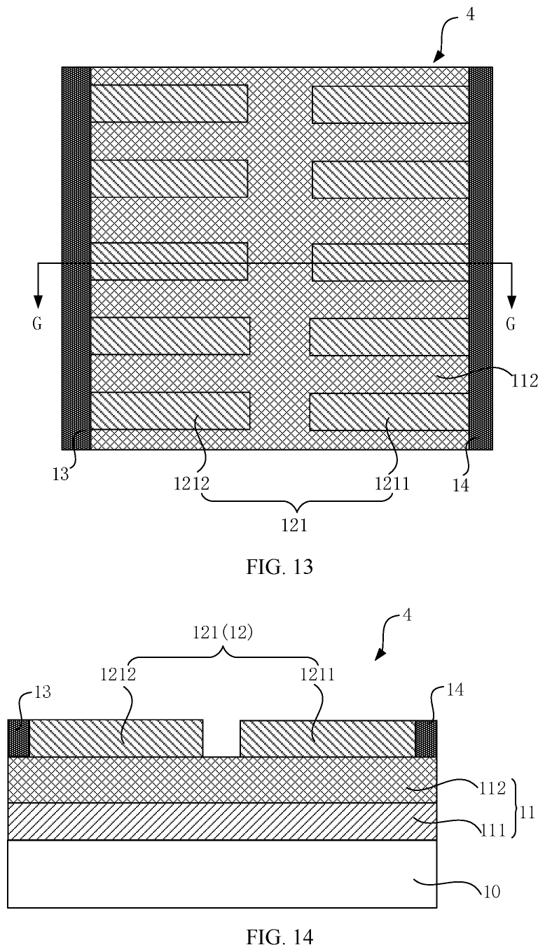

FIG. 13 is a top view illustrating a Schottky barrier diode according to a fourth embodiment of the present disclosure. FIG. 14 is a sectional view along line GG in FIG. 13.

Referring to FIG. 13 and FIG. 14, the Schottky barrier diode 4 of this fourth embodiment is substantially the same as the Schottky barrier diodes 1, 2, and 3 of the first to third embodiments, the difference is only that in the fourth embodiment, each P-type semiconductor sub-block 121 is separated into a first section 1211 and a second section 1212 insulated from each other, the side surface of the first section 1211 contacts the cathode 14 and does not contact the anode 13, and the side surface of the second section 1212 contacts the anode 13 and does not contact the cathode 14.

In the Schottky barrier diode 4, when reverse offset, the first section 1211 and the cathode 14 are equipotential, and the depletion layer formed below the first section 1211, although still confined within the barrier layer 112, becomes deeper in depth compared to the depletion layer of the Schottky barrier diode 1 of the first embodiment; the second section 1212 and the anode 13 are equipotential, and the depletion layer formed below the second section 1212, although still confined within the barrier layer 112, becomes shallower in depth compared to the depletion layer of the Schottky barrier diode 1 of the first embodiment. Thus, the surface electric field of the heterojunction structure 11 between the anode 13 and the cathode 14 can be further redistributed.

In other embodiments, it is also possible that each of some of the plurality of P-type semiconductor sub-blocks 121 is separated into a first section 1211 and a second section 1212 insulated from each other, where the side surface of the first section 1211 contacts the cathode 14 and does not contact the anode 13, and the side surface of the second section 1212 contacts the anode 13 and does not contact the cathode 14, side surfaces of some of the plurality of P-type semiconductor sub-blocks 121 contact the cathode 14 and do not contact the anode 13, side surfaces of some of the plurality of P-type semiconductor sub-blocks 121 contact the anode 13 and do not contact the cathode 14. In addition, side surfaces of the rest of the plurality of P-type semiconductor sub-blocks 121 neither contact the anode 13 nor the cathode 14.

Accordingly, a method for manufacturing the Schottky barrier diode 4 of this fourth embodiment differs from the method for manufacturing the Schottky barrier diodes 1, 2, and 3 of the first to third embodiments only in that: in step S1, specifically, in step S12, when the whole P-type semiconductor layer is patterned, at least one of the formed P-type semiconductor sub-blocks 121 is separated into the first segment 1211 and the second segment 1212 insulated from each other; in step S2, the step of forming the anode 13 and the cathode 14 includes: forming the cathode 14 in contact with the side surface of the first section 1211 and forming the anode 13 in contact with the side surface of the second section 1212.

In this embodiment, after forming the anode 13 and the cathode 14, a part of the contacted P-type semiconductor sub-block 121 can be removed.

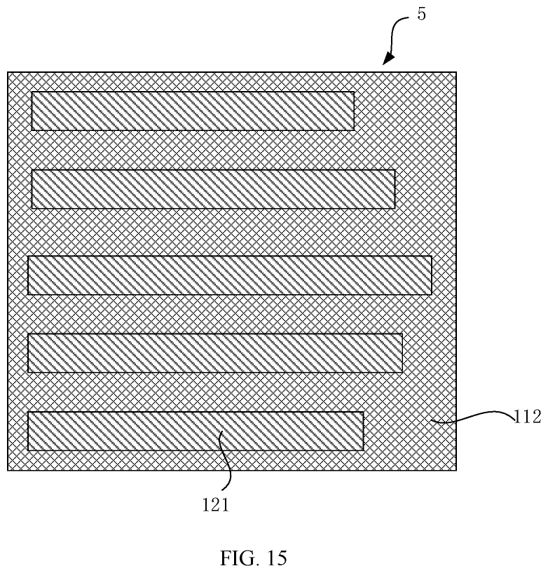

FIG. 15 is a top view illustrating a Schottky barrier diode without an anode and a cathode according to a fifth embodiment of the present disclosure.

Referring to FIG. 15, the Schottky barrier diode 5 of this fifth embodiment is substantially the same as the Schottky barrier diodes 1, 2, 3, and 4 of the first to fourth embodiments, the difference is only that in the fifth embodiment, the plurality of P-type semiconductor sub-blocks 121 extend between the anode 13 and the cathode 14 for different lengths.

For example, the length of each P-type semiconductor sub-block 121 extending between the anode 13 and the cathode 14 may be set according to the improved electric field distribution at the lower edges of the anode 13 and the cathode 14.

In other embodiments, at least two of the plurality of P-type semiconductor sub-blocks 121 may extend between the anode 13 and the cathode 14 for unequal lengths.

Accordingly, a method for manufacturing the Schottky barrier diode 5 of this fifth embodiment differs from the method of manufacturing the Schottky barrier diodes 1, 2, 3, and 4 of the first to fourth embodiments only in that: in step S1, specifically, in step S12, the lengths of the plurality of P-type semiconductor sub-blocks 121 formed when patterning the whole P-type semiconductor layer, are different.

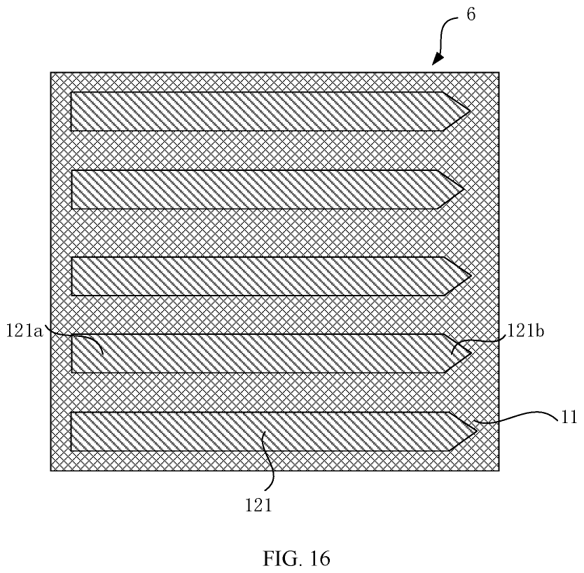

FIG. 16 is a top view illustrating a Schottky barrier diode without an anode and a cathode according to a sixth embodiment of the present disclosure.

Referring to FIG. 16, the Schottky barrier diode 6 of this sixth embodiment is substantially the same as the Schottky barrier diodes 1, 2, 3, 4, and 5 of the first to fifth embodiments, the difference is only that in the sixth embodiment, each of the plurality of P-type semiconductor sub-blocks 121 includes a first end 121a close to the anode 13 and a second end 121b close to the cathode 14; each of the plurality of P-type semiconductor sub-blocks 121 has a tip at the second end 121b.

In other embodiments, the first end 121a of each of the plurality of P-type semiconductor sub-blocks 121 may also have a tip, or the first end 121a and the second end 121b of each of the plurality of P-type semiconductor sub-blocks 121 may have a tip, or the first end 121a and/or the second end 121b of some of the plurality of P-type semiconductor sub-blocks 121 have a tip.

The above-mentioned tip may be repeated for several cycles to become serrated.

For example, the shapes of the first end 121a and the second end 121b of each P-type semiconductor sub-block 121 may be set according to the improved electric field distribution at the lower edges of the anode 13 and the cathode 14.

Accordingly, a method for manufacturing the Schottky barrier diode 6 of this sixth embodiment differs from the method for manufacturing the Schottky barrier diodes 1, 2, 3, 4, and 5 of the first to fifth embodiment only in that: in step S1, specifically step S12, the second end 121b of each of the plurality of P-type semiconductor sub-blocks 121 formed when patterning the whole P-type semiconductor layer is shaped to have a tip.

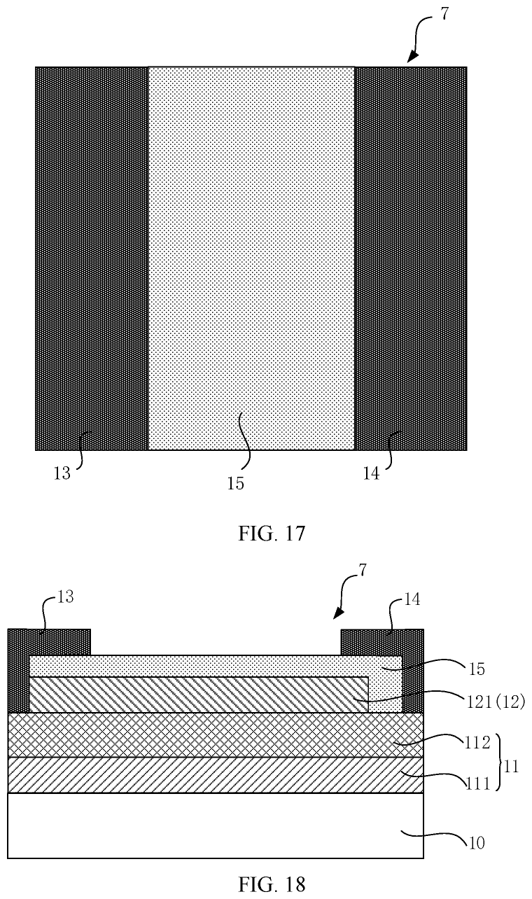

FIG. 17 is a top view illustrating a Schottky barrier diode according to a seventh embodiment of the present disclosure; and FIG. 18 is a sectional view along a P-type semiconductor sub-block of the Schottky barrier diode of FIG. 17.

Referring to FIG. 17 and FIG. 18, the Schottky barrier diode 7 of this seventh embodiment is substantially the same as the Schottky barrier diodes 1, 2, 3, 4, 5, and 6 of the first to sixth embodiments, the difference is only that in the seventh embodiment, a passivation layer 15 is further included, the passivation layer 15 integrally covers on the plurality of P-type semiconductor sub-blocks 121 and between the plurality of P-type semiconductor sub-blocks 121.

In this seventh embodiment, a part of the anode 13 and a part of the cathode 14 are disposed on the passivation layer 15, and another part of the anode 13 and another part of the cathode 14 pass through the passivation layer 15 to contact the heterojunction structure 11.

In this embodiment, a material of the passivation layer 15 may be SiN, SiO₂, SiON, Al₂O₃, MgO, Ga₂O₃, or HfO₂ for isolating external water oxygen from entering the P-type semiconductor layer 12 and the heterojunction structure 11.

Accordingly, a method for manufacturing the Schottky barrier diode 7 of this seventh embodiment differs from the method for manufacturing the Schottky barrier diodes 1, 2, 3, 4, 5, and 6 of the first to sixth embodiments only in that: between epitaxially growing the P-type semiconductor layer 12 in step S1 and forming the anode 13 and the cathode 14 in step S2, the method further includes: integrally forming a passivation layer 15 on the plurality of P-type semiconductor subblocks 121 and on the heterojunction structure 11 exposed between the plurality of P-type semiconductor sub-blocks 121.

A material of the passivation layer 15 may be SiN, SiO₂, SiON, Al₂O₃, MgO, Ga₂O₃, or HfO₂, and accordingly, the passivation layer 15 may be formed by physical vapor deposition or chemical vapor deposition.

In this embodiment, with reference to FIG. 17 and FIG. 18, when forming the anode 13 and the cathode 14, a part of each of the plurality of P-type semiconductor sub-blocks 121 and a part of the passivation layer 15 may be removed. In other embodiments, when forming the anode 13 and the cathode 14, only a part of the passivation layer 15 may also be removed.

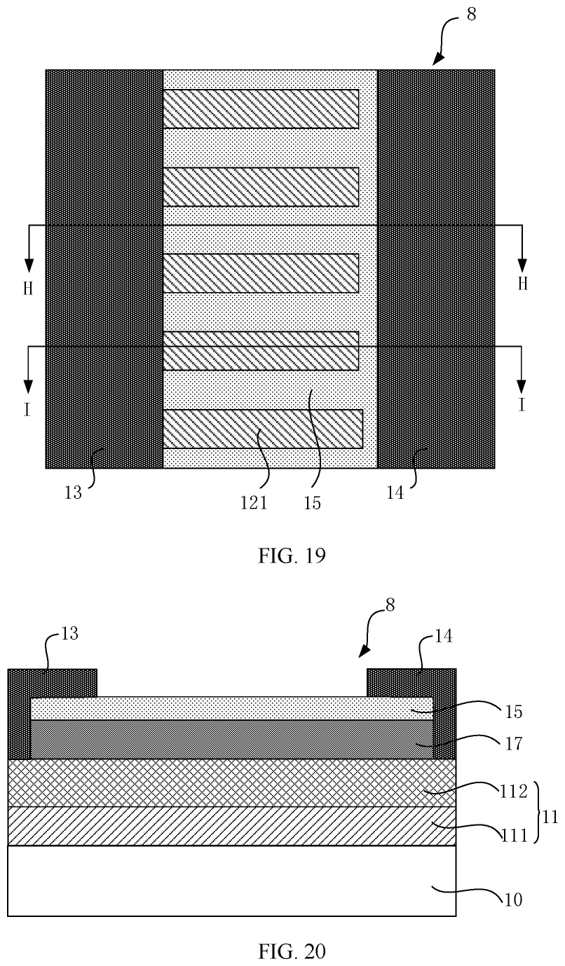

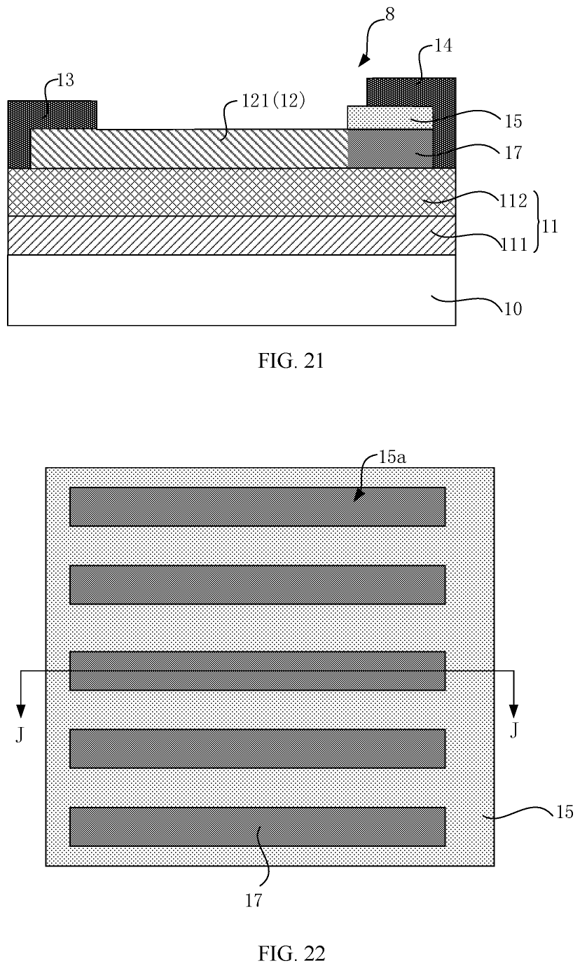

FIG. 19 is a top view illustrating a Schottky barrier diode according to an eighth embodiment of the present disclosure. FIG. 20 is a sectional view along line HH in FIG. 19. FIG. 21 is a sectional view along line II in FIG. 19. In other words, in FIG. 20, the line HH passes through the position of the first ion-doped layer of the Schottky barrier diode; and in FIG. 21, the line II passes through the position of the P-type semiconductor sub-block of the Schottky barrier diode.

Referring to FIGS. 19 to 21, the Schottky barrier diode 8 of this eighth embodiment is substantially the same as the Schottky barrier diodes 1, 2, 3, 4, 5, 6, and 7 of the first to seventh embodiments, the difference is only that in the eighth embodiment, the plurality P-type semiconductor sub-blocks 121 are connected to the first ion-doped layer 17, and the passivation layer 15 is disposed on the first ion-doped layer 17 and exposes the P-type semiconductor sub-blocks 121. In other words, the passivation layer 15 is not formed in one piece, but only on the first ion-doped layer 17 between adjacent P-type semiconductor sub-blocks 121.

In this embodiment, the side surface of each P-type semiconductor sub-block 121 contacts the anode 13 and does not contact the cathode 14. A part of the anode 13 is disposed on each P-type semiconductor sub-block 121, and another part of the anode 13 passes through the passivation layer 15 and the first ion-doped layer 17 to contact the heterojunction structure 11. A part of the cathode 14 is disposed on the passivation layer 15, and another part of the cathode 14 passes through the passivation layer 15 and the first ion-doped layer 17 to contact the heterojunction structure 11. The part of the anode 13 disposed on each P-type semiconductor sub-block 121 reduces the turn-on voltage of the Schottky barrier diode 8, provides better reverse conduction performance, prevents avalanche breakdown during reverse conduction, and improves the reliability of the Schottky barrier diode 8.

In other embodiments, the side surface of each P-type semiconductor sub-block 121 may also contact the cathode 14 and does not contact the anode 13. A part of the cathode 14 is disposed on each P-type semiconductor sub-block 121, and another part to the cathode 14 passes through the passivation layer 15 and the first ion-doped layer 17 to contact the heterojunction structure 11; or each P-type semiconductor sub-block 121 is separated into a first section 1211 and a second section 1212 insulated from each other, the side surface of the first section 1211 contacts the cathode 14 and does not contact the anode 13, and the side surface of the second section 1212 contacts the anode 13 and does not contact the cathode 14. A part of the cathode 14 is disposed on the first section 1211, and another part of the cathode 14 passes through the passivation layer 15 and the first ion-doped layer 17 to contact the heterojunction structure 11. A part of the anode 13 is disposed on the second section 1212, and another part of the anode 13 passes through the passivation layer 15 and the first ion-doped layer 17 to contact the heterojunction structure 11.

Accordingly, a method for manufacturing the Schottky barrier diode 8 of this eighth embodiment differs from the method for manufacturing the Schottky barrier diodes 1, 2, 3, 4, 5, 6 and 7 of the first to seventh embodiments only in that step S1 includes steps S11′ to S12′.

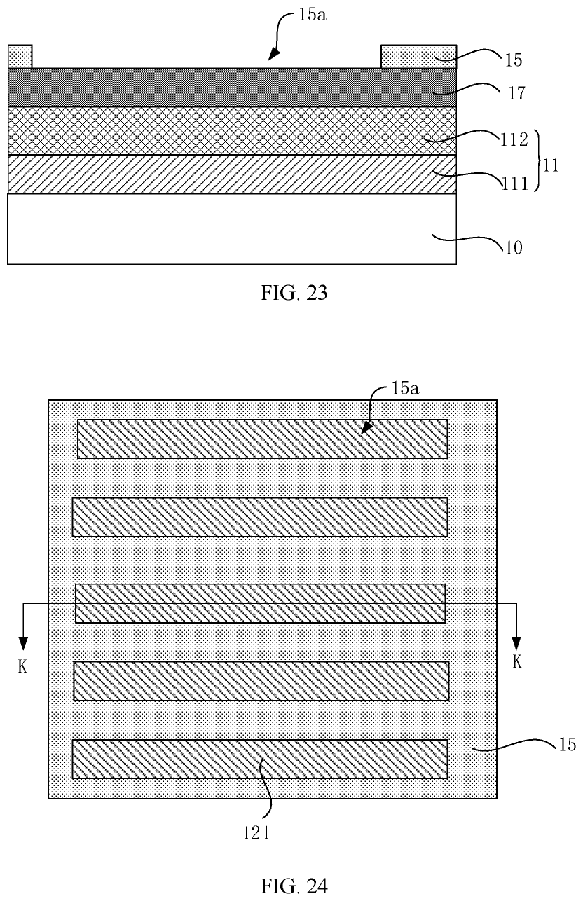

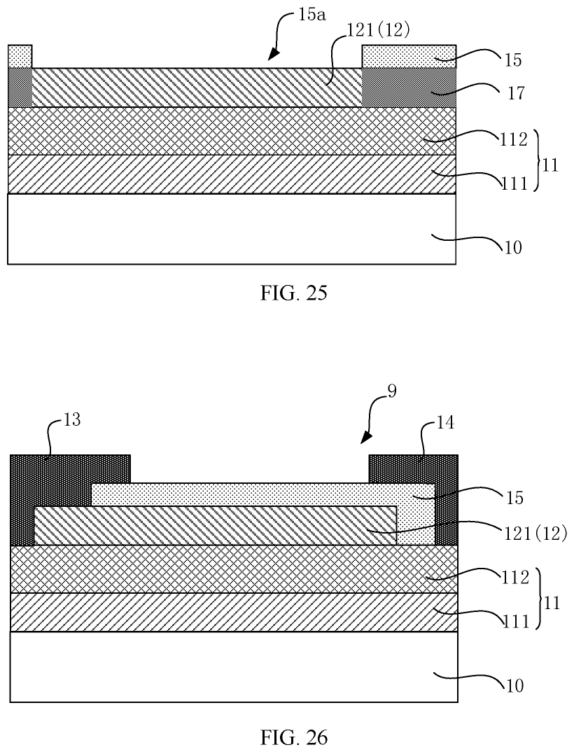

FIGS. 22 to 25 are schematic diagrams illustrating intermediate structures corresponding to a method for manufacturing the Schottky barrier diode of FIGS. 19 to 21. FIG. 22 illustrates a patterned passivation layer added to the first ion-doped layer; FIG. 23 is a sectional view along line JJ in FIG. 22; FIG. 24 is a schematic diagram illustrating a structure formed after the dopant ions of the first ion-doped layer exposed in FIG. 22 are activated; and FIG. 25 is a sectional view along line KK in FIG. 24.

At step S11′, referring to FIG. 22 and FIG. 23, the first ion-doped layer 17 is epitaxially grown on an entire surface of the heterojunction structure 11, and a patterned passivation layer 15 is formed on the first ion-doped layer 17, where the patterned passivation layer 15 has a plurality of first openings 15a, the plurality of first openings 15a are spaced apart in a first direction, and an angle is formed between an extending direction of each of the plurality of first openings 15a and the first direction, where the angle is greater than 0° and less than or equal to 90°.

At step S12′, with reference to FIG. 24 and FIG. 25, the dopant ions in the first ion-doped layer 17 exposed with the patterned passivation layer 15 as a mask are activated to form the plurality of P-type semiconductor sub-blocks 121.

Activation of the dopant ions in the first ion-doped layer 17 may be achieved by an annealing process.

FIG. 26 is a schematic diagram illustrating a cross-sectional structure of a Schottky barrier diode according to a ninth embodiment of the present disclosure.

Referring to FIG. 26, the Schottky barrier diode 9 of this ninth embodiment is substantially the same as the Schottky barrier diodes 1, 2, 3, 4, 5, 6, 7 and 8 of the first to eighth embodiments, the difference is only that in the ninth embodiment, the passivation layer 15 exposes a part of an upper surface of at least one of the plurality of P-type semiconductor sub-blocks 121, and the anode 13 also contacts the exposed part of the upper surface of the at least one of the plurality of P-type semiconductor sub-blocks 121. In other words, the anode 13 contacts the exposed part of the upper surface and a side surface of the at least one of the plurality of P-type semiconductor sub-blocks 121 and the heterojunction structure 11.

Compared to the anode 13 directly contacting the barrier layer 112, the anode 13 contacting the upper surface of the exposed P-type semiconductor sub-block 121 can balance the Schottky barrier diode 9 in terms of forward turn-on voltage and reverse leakage characteristics, and can effectively suppress a leakage characteristic of the heterojunction structure 11 in a high temperature environment.

For the embodiment without the passivation layer 15, the anode 13 contacts the side surface of each P-type semiconductor sub-block 121 and the upper surface of at least one P-type semiconductor sub-block 121.

Accordingly, a method for manufacturing the Schottky barrier diode 9 of this ninth embodiment differs from the method for manufacturing the Schottky barrier diodes 1, 2, 3, 4, 5, 6, 7 and 8 of the first to eighth embodiments only in that: in step S2, the passivation layer 15 is etched to expose the heterojunction structure 11 and a part of a upper surface of at least one P-type semiconductor sub-block 121, and the anode 13 contacts the exposed upper surface and the side surface of the at least one P-type semiconductor sub-block 121, and the heterojunction structure 11.

In other embodiments, the passivation layer 15 exposes a part of the upper surface of the at least one P-type semiconductor sub-block 121, and the cathode 14 contacts the exposed upper surface of the at least one P-type semiconductor subblock 121. In other words, the cathode 14 contacts the exposed upper surface and the side surface of the at least one P-type semiconductor subblock 121, and the heterojunction structure 11.

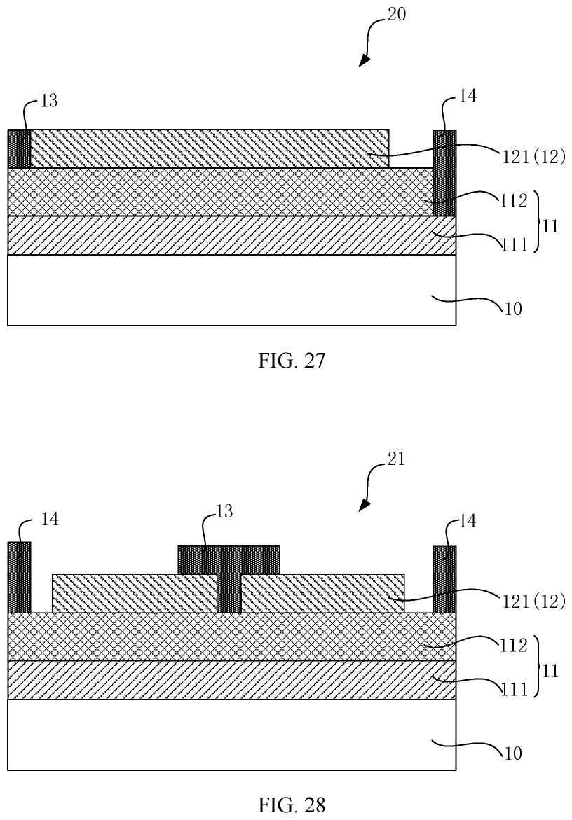

FIG. 27 is a schematic diagram illustrating a cross-sectional structure of a Schottky barrier diode according to a tenth embodiment of the present disclosure.

Referring to FIG. 27, the Schottky barrier diode 20 of this tenth embodiment is substantially the same as the Schottky barrier diodes 1, 2, 3, 4, 5, 6, 7, 8 and 9 of the first to ninth embodiments, the difference is only that in the tenth embodiment, the anode 13 contacts the barrier layer 112, and the cathode 14 contacts the channel layer 111. in other words, a Schottky contact is formed between the anode 13 and the barrier layer 112, and an ohmic contact is formed between the cathode 14 and the channel layer 111.

In other embodiments, the anode 13 may contact at least one of the barrier layer 112 or the channel layer 111, and a Schottky contact is formed between the anode 13 and the contacted layer. The cathode 14 may contact at least one of the barrier layer 112 or the channel layer 111, and an ohmic contact is formed between the cathode 14 and the contacted layer.

Accordingly, a method for manufacturing the Schottky barrier diode 20 of this tenth embodiment differs from the method for manufacturing the Schottky barrier diodes 1, 2, 3, 4, 5, 6, 7, 8 and 9 of the first to ninth embodiments only in that: in step S2, the anode 13 may contact at least one of the barrier layer 112 or the channel layer 111, and a Schottky contact is formed between the anode 13 and the contacted layer. The cathode 14 may contact at least one of the barrier layer 112 or the channel layer 111, and an ohmic contact is formed between the cathode 14 and the contacted layer.

It will be noted that in this embodiment, the anode 13 contacting at least one of the barrier layer 112 or the channel layer 111 means that the anode 13 contacts the upper surface of the barrier layer 112, or contacts the upper surface of the channel layer 111, or contacts both the upper surface of the channel layer 111 and the upper surface of the barrier layer 112. The cathode 14 contacting at least one of the barrier layer 112 or the channel layer 111 means that the cathode 14 contacts the upper surface of the barrier layer 112, or contacts the upper surface of the channel layer 111, or contacts both the upper surface of the channel layer 111 and the upper surface of the barrier layer 112.

FIG. 28 is a schematic diagram illustrating a cross-sectional structure of a Schottky barrier diode according to an eleventh embodiment of the present disclosure.

Referring to FIG. 28, the Schottky barrier diode 21 of this eleventh embodiment is substantially the same as the Schottky barrier diodes 1, 2, 3, 4, 5, 6, 7, 8, 9 and 20 of the first to tenth embodiments, the difference is only that the cathode 14 is in the shape of a ring.

Accordingly, a method for manufacturing the Schottky barrier diode 21 of this eleventh embodiment differs from the method for manufacturing the Schottky barrier diodes 1, 2, 3, 4, 5, 6, 7, 8, 9 and 20 of the first to tenth embodiments only in that: in step S2, the cathode 14 is made in the shape of a ring.

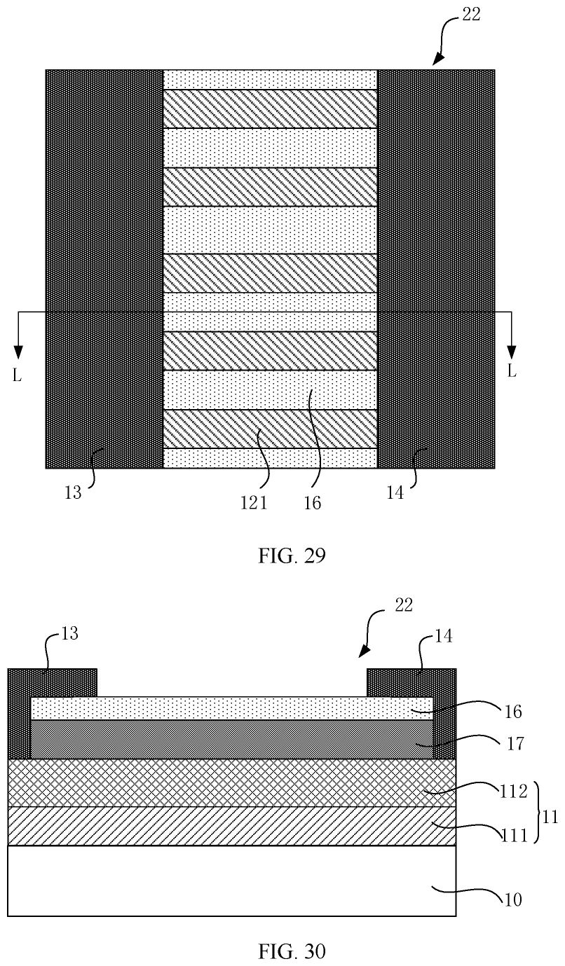

FIG. 29 is a top view illustrating a Schottky barrier diode according to a twelfth embodiment of the present disclosure. FIG. 30 is a sectional view along line LL in FIG. 29. In other words, in FIG. 29, the line LL passes through the position of the N-type semiconductor layer of the Schottky barrier diode.

Referring to FIG. 29 and FIG. 30, the Schottky barrier diode 22 of this twelfth embodiment is substantially the same as the Schottky barrier diodes 8, 9, 20 and 21 of the seventh to eleventh embodiments, the difference is only that in the twelfth embodiment, the passivation layer 15 in the Schottky barrier diode 8 of the eighth embodiment is replaced with an N-type semiconductor layer 16. In other words, the plurality of P-type semiconductor sub-blocks 121 are connected to the first ion-doped layer 17, the N-type semiconductor layer 16 is disposed on the first ion-doped layer 17 and expose the plurality of the P-type semiconductor sub-block 121.

Accordingly, a method for manufacturing the Schottky barrier diode 22 of this twelfth embodiment differs from the method for manufacturing the Schottky barrier diodes 8, 9, 20 and 21 of the seventh to eleventh embodiments only in that: the passivation layer 15 is replaced with the N-type semiconductor layer 16 in step S11′ of the method for manufacturing the Schottky barrier diode 8 of the eighth embodiment.

Specifically, the step of epitaxially growing the P-type semiconductor layer 12 includes: epitaxially growing the first ion-doped layer 17 and the N-type semiconductor layer 16 in sequence over an entire surface of the heterojunction structure; patterning the N-type semiconductor layer 16, such that the N-type semiconductor layer 16 has a plurality of second openings, wherein an angle is formed between an extending direction of each of the plurality of second openings and the first direction, the angle is greater than 0° and less than or equal to 90°; and activating dopant ions in the first ion-doped layer 17 exposed with the N-type semiconductor layer 16 as a mask to form the plurality of P-type semiconductor sub-blocks 121.

A material of the N-type semiconductor layer 16 may be a GaN-based material, and the N-type doping element may be at least one of Si, Ge, Sn, Se, or Te.

Although the present disclosure is disclosed as above, the present disclosure is not limited thereto. Those skilled in the art may make various changes and modifications without departing from the spirit and scope of the present disclosure, and therefore the scope of the present disclosure should be subject to the scope defined by the claims.

What is claimed is:

1. A Schottky barrier diode, comprising:
a substrate;
a heterojunction structure disposed on the substrate; and
a P-type semiconductor layer, an anode and a cathode disposed on the heterojunction structure, wherein the P-type semiconductor layer comprises a plurality of P-type semiconductor sub-blocks, the anode and the cathode are disposed at two ends in an extending direction of the plurality of P-type semiconductor sub-blocks, respectively, and the plurality of P-type semiconductor sub-blocks between the anode and the cathode are spaced apart.

2. The Schottky barrier diode of claim 1, wherein the plurality of P-type semiconductor sub-blocks are distributed in parallel with each other between the anode and the cathode.

3. The Schottky barrier diode of claim 1, wherein at least two of the plurality of P-type semiconductor sub-blocks extend between the anode and the cathode for unequal lengths.

4. The Schottky barrier diode of claim 1, wherein for each of the plurality of P-type semiconductor sub-blocks, the P-type semiconductor sub-block comprises a first end close to the anode and a second end close to the cathode; and at least one of:
the first end of at least one of the plurality of P-type semiconductor sub-blocks has a tip, or
the second end of at least one of the plurality of P-type semiconductor sub-blocks has a tip.

5. The Schottky barrier diode of claim 1, further comprising:
a passivation layer; and
a first ion-doped layer, wherein the first ion-doped layer is disposed between the plurality of P-type semiconductor sub-blocks, the plurality of P-type semiconductor sub-blocks are connected to the first ion-doped layer, the passivation layer is disposed on the first ion-doped layer and exposes the plurality of P-type semiconductor sub-blocks; and the anode and the cathode both pass through the passivation layer and the first ion-doped layer to contact the heterojunction structure.

6. The Schottky barrier diode of claim 1, further comprising:
a passivation layer, wherein the passivation layer integrally covers on the plurality of P-type semiconductor sub-blocks and between the plurality of P-type semiconductor sub-blocks; and the anode and the cathode pass through the passivation layer to contact the heterojunction structure.

7. The Schottky barrier diode of claim 1, wherein
a side surface of at least one of the plurality of P-type semiconductor sub-blocks contacts the anode and does not contact the cathode; or
a side surface of at least one of the plurality of P-type semiconductor sub-blocks contacts the cathode and does not contact the anode; or
at least one of the plurality of P-type semiconductor sub-blocks is separated into a first section and a second section insulated from each other, wherein a side surface of the first section contacts the cathode and does not contact the anode, and a side surface of the second section contacts the anode and does not contact the cathode.

8. The Schottky barrier diode of claim 1, wherein
the anode contacts side surfaces of the plurality of P-type semiconductor sub-blocks and an upper surface of at least one of the plurality of P-type semiconductor sub-blocks; or
the cathode contacts side surfaces of the plurality of P-type semiconductor sub-block and an upper surface of at least one of the plurality of P-type semiconductor sub-blocks.

9. The Schottky barrier diode of claim 1, wherein the heterojunction structure comprises:
a channel layer close to the substrate; and
a barrier layer away from the substrate;
wherein the anode contacts the barrier layer, or contacts the channel layer, or contacts both the channel layer and the barrier layer; and the cathode contacts the barrier layer, or contacts the channel layer, or contacts both the channel layer and the barrier layer.

10. The Schottky barrier diode of claim 1, further comprising:
an N-type semiconductor layer; and
a first ion-doped layer;
wherein the first ion-doped layer is disposed between the plurality of P-type semiconductor sub-blocks, the plurality of P-type semiconductor sub-blocks are connected to the first ion-doped layer, and the N-type semiconductor layer is disposed on the first ion-doped layer and exposes the plurality of P-type semiconductor sub-blocks.

11. A method for manufacturing a Schottky barrier diode, comprising:
epitaxially growing a heterojunction structure and a P-type semiconductor layer in sequence on a substrate, wherein the P-type semiconductor layer comprises a plurality of P-type semiconductor sub-blocks, the plurality of P-type semiconductor sub-blocks are spaced apart in a first direction, an angle is formed between an extending direction of each of the plurality of P-type semiconductor sub-blocks and the first direction, and the angle is greater than 0° and less than or equal to 90°; and
forming an anode and a cathode on the heterojunction structure, wherein the anode and the cathode are disposed at two ends in the extending direction of the plurality of P-type semiconductor sub-blocks, respectively.

12. The method of claim 11, wherein epitaxially growing the P-type semiconductor layer comprises:
epitaxially growing a first ion-doped layer over an entire surface of the heterojunction structure;
forming a patterned passivation layer on the first ion-doped layer, wherein the patterned passivation layer has a plurality of first openings, the plurality of first openings are spaced apart in the first direction, an angle is formed between an extending direction of each of the plurality of first openings and the first direction, and the angle is greater than 0° and less than or equal to 90°; and
activating exposed dopant ions in the first ion-doped layer with the patterned passivation layer as a mask to form the plurality of P-type semiconductor sub-blocks.

13. The method of claim 11, wherein epitaxially growing the P-type semiconductor layer comprises:
epitaxially growing a first ion-doped layer over an entire surface of the heterojunction structure and activating the first ion-doped layer to form a whole P-type semiconductor layer; and
patterning the whole P-type semiconductor layer to form the plurality of P-type semiconductor sub-blocks.

14. The method of claim 13, wherein between epitaxially growing the P-type semiconductor layer and forming the anode and the cathode, the method further comprising:
integrally forming a passivation layer on the heterojunction structure exposed between the plurality of P-type semiconductor sub-blocks, wherein the anode and the cathode pass through the passivation layer to contact the heterojunction structure.

15. The method of claim 12, wherein
forming the anode comprises: etching the passivation layer to expose the heterojunction structure and a part of an upper surface of at least one of the plurality of P-type semiconductor sub-blocks, wherein the anode contacts the exposed part of the upper surface and a side surface of the at least one of the plurality of P-type semiconductor sub-blocks and the heterojunction structure; or
forming the cathode comprises: etching the passivation layer to expose the heterojunction structure and a part of an upper surface of at least one of the plurality of P-type semiconductor sub-blocks, wherein the cathode contacts the exposed part of the upper surface and a side surface of the at least one of the plurality of P-type semiconductor sub-blocks and the heterojunction structure.

16. The method of claim 11, wherein epitaxially growing the P-type semiconductor layer comprises:
epitaxially growing a first ion-doped layer and an N-type semiconductor layer in sequence over an entire surface of the heterojunction structure;
patterning the N-type semiconductor layer, such that the N-type semiconductor layer has a plurality of second openings, wherein an angle is formed between an extending direction of each of the plurality of second openings and the first direction, and the angle is greater than 0° and less than or equal to 90°; and
activating exposed dopant ions in the first ion-doped layer with the N-type semiconductor layer as a mask to form the plurality of P-type semiconductor sub-blocks.

17. The method of claim 11, wherein forming the anode and the cathode comprises:
forming the anode in contact with a side surface of at least one of the plurality of P-type semiconductor sub-blocks and the cathode not in contact with another side surface of the at least one of the plurality of P-type semiconductor sub-blocks, wherein a normal line of the side surface is parallel to a normal line of the another side surface and is parallel to the plane of the substrate; or
forming the cathode in contact with a side surface of at least one of the plurality of P-type semiconductor sub-blocks and the anode not in contact with another side surface of the at least one of the plurality of P-type semiconductor sub-blocks, wherein a normal line of the side surface is parallel to a normal line of the another side surface and is parallel to the plane of the substrate; or
separating at least one of the plurality of P-type semiconductor sub-blocks into a first section and a second section insulated from each other, forming the cathode in contact with a side surface of the first section, and forming the anode in contact with a side surface of the second section.
